(19) United States
(12) Patent Application Publication
(10) Pub. No.: US 2026/0324474 A1
(43) Pub. Date: Oct. 15, 2026

(54) EMBEDDED WAFER LEVEL BALL GRID ARRAY PACKAGES

(71) Applicant: HUAWEI TECHNOLOGIES CO., LTD., Shenzhen (CN)

(72) Inventors: Mario Costa, Milan (IT); Wenqin Yan, Xi'an (CN); Junpeng Wang, Xi'an (CN); Haiming Fan, Shenzhen (CN)

(21) Appl. No.: 19/687,339

(22) Filed: May 26, 2026

Related U.S. Application Data
(63) Continuation of application No. PCT/CN2023/134273, filed on Nov. 27, 2023.

(51) Int. Cl. H10W 70/65; H05K 1/02; H05K 1/181; H10W 44/20; H10W 70/652

(52) U.S. Cl. CPC H10W 70/657; H05K 1/0243; H05K 1/181; H10W 44/216; H10W 44/251; H10W 70/652; H05K 2201/10098

(57) ABSTRACT

The present disclosure relates to an embedded wafer level ball grid array package (eWLB package). The eWLB package comprises a mold enclosing an integrated circuit, a dielectric entity arranged in the mold, and a microstrip line electrically connected with the integrated circuit. In a direction towards a connection side of the eWLB package comprising connection elements, an end part of the microstrip line is arranged below the dielectric entity. The dielectric entity has a dimension perpendicular to the microstrip line equaling a quarter of a wavelength for which the microstrip line is designed. The eWLB package is configured to be connected via the connection elements to a printed circuit board (PCB) with a waveguide in the form of a passageway opening in the PCB, such that the dielectric entity and the end part of the microstrip line are aligned with the waveguide.

### CROSS-REFERENCE TO RELATED APPLICATIONS

This application is a continuation of International Application No. PCT/CN2023/134273, filed on Nov. 27, 2023, the disclosure of which is hereby incorporated by reference in its entirety.

### TECHNICAL FIELD

The present disclosure relates to embedded wafer level ball grid array packages (eWLB packages) and systems comprising a eWLB package of such eWLB packages and a printed circuit board (PCB) with a waveguide in the form of a passageway opening in the PCB.

### BACKGROUND

The embedded wafer level ball grid array package (eWLB packages) was developed for improving a connection of packages to printed circuit boards (PCBs).

### SUMMARY

A eWLB package may be used for packaging an integrated circuit configured for a communication. Optionally, it may be desired that the integrated circuit is configured to provide signals, such as radio frequency (RF) signals, to an external waveguide.

In view of the above, this disclosure aims to provide a eWLB package that packages an integrated circuit and allows the integrated circuit to provide signals to outside the package. An objective of this disclosure may be to provide such a eWLB package that allows the integrated circuit to provide signals to an external waveguide.

These and other objectives are achieved by the solution of this disclosure as described in the independent claims. Advantageous implementations are further defined in the dependent claims.

A first aspect of this disclosure provides an embedded wafer level ball grid array package (eWLB package). The eWLB package comprises a mold enclosing an integrated circuit, a dielectric entity arranged in the mold, and a microstrip line electrically connected with the integrated circuit. In a direction towards a connection side of the eWLB package comprising connection elements, an end part of the microstrip line is arranged below the dielectric entity. The dielectric entity has a dimension perpendicular to the microstrip line equaling a quarter of a wavelength for which the microstrip line is designed. The eWLB package is configured to be connected via the connection elements to a printed circuit board (PCB) with a waveguide in the form of a passageway opening in the PCB, such that the dielectric entity and the end part of the microstrip line are aligned with the waveguide.

In other words, the first aspect proposes a eWLB package packaging an integrated circuit by enclosing the integrated circuit in a mold of the eWLB package. The eWLB package further comprises a dielectric entity arranged in the mold and a microstrip line electrically connected with the integrated circuit, wherein an end part of the microstrip line is arranged below the dielectric entity. The microstrip line and the dielectric entity allow the integrated circuit to provide signals to outside the eWLB package and/or obtain signals from outside the eWLB package. Such signals may be for example radio frequency (RF) signals. Especially, due to the arrangement of the microstrip line and the dielectric entity in the eWLB package and with regard to each other, the integrated circuit may provide signals via the microstrip line and the dielectric entity in the direction of the connection side of the eWLB. This allows providing signals from the integrated circuit to a waveguide in the form of a passageway opening in the PCB when the eWLB is arranged on the PCB.

The dielectric entity having the dimension perpendicular to the microstrip line that equals a quarter of a wavelength for which the microstrip line is designed increases an operative relative frequency bandwidth of the eWLB package, especially for providing and/or obtaining RF signals by the integrated circuit. This allows providing a wide operative relative frequency bandwidth of a communication, for which the integrated circuit may be configured. For example, the operative relative frequency bandwidth may be 40%. The operative relative frequency bandwidth is a frequency band for which the eWLB package may be designed. In contrast thereto, in case of implementing the end of the microstrip line as a patch radiator instead of using and arranging the dielectric entity and the microstrip line according to the first aspect of the disclosure, the operative relative frequency bandwidth would be narrow, around 20%. In contrast to the first aspect, in case of arranging a prefabricated laminate insert (that is placed like chips during the reconstitution process of the eWLB process flow) in the eWLB package for providing signals at a side opposite to the connection side of the eWLB package instead of using and arranging the dielectric entity according to the first aspect, the operative relative frequency bandwidth would be narrow, around 20%.

The arrangement of the dielectric entity and the microstrip line in the eWLB package allows signals, such as RF signals, from the integrated circuit to travel via the microstrip line and the dielectric entity towards the connection side of the eWLB package and, thus, to the waveguide of the PCB when the eWLB package is arranged on the PCB such that the dielectric entity and the end part of the microstrip line are aligned with the waveguide. This allows improving a system architecture of a system comprising the eWLB package and the PCB with the waveguide. Namely, in case the signals from the integrated circuit would leave the eWLB package at a different side than the connection side of the eWLB package, the signals would have to be guided by additional components to the waveguide of the PCB.

The mold may be a plastic mold. The integrated circuit may be a monolithic microwave integrated circuit (MMIC). The integrated circuit may represent a die of the eWLB package. The integrated circuit may be configured to generate and provide signals, such as RF signals, to the microstrip line. The integrated circuit may be configured to communicate by providing or obtaining signals, such as RF signals, to or from, respectively, the microstrip line. The integrated circuit may be configured to provide signals in the form of electromagnetic waves to the microstrip line. For example, the integrated circuit may be configured to provide RF signals in the form of radio waves to the microstrip line. The integrated circuit may be configured to obtain signals (e.g. RF signals) in the form of electromagnetic waves (e.g. radio waves) from the microstrip line. For example, the microstrip line may be configured such that signals from the integrated circuit travel in the form of a transverse electromagnetic mode (TEM) via the microstrip line.

The dielectric entity is three-dimensional. The “dielectric entity” may be referred to as “dielectric insert” or “dielectric block”. The dielectric entity represents a waveguide structure. The dielectric entity may be prefabricated (e.g. a prefabricated dielectric insert or prefabricated dielectric block). The prefabricated dielectric entity may be placed like a chip during a reconstitution process of an eWLB process flow producing the eWLB package. Optionally, the dielectric entity may be formed by molding a glass wafer, where the dielectric entity may be directly formed, with one or more cavities in the glass for one or more dies (i.e. one or more chips).

The end part of the microstrip line may be arranged with regard to the dielectric entity such that a transverse electromagnetic mode (TEM) of the microstrip line transitions to a transverse electric mode (TE) of the dielectric entity representing a waveguide. In other words, the microstrip line and the dielectric entity may implement a waveguide transition from the transverse electromagnetic mode (TEM) of the microstrip line to the transverse electric mode (TE) of the dielectric entity representing a waveguide structure. The transverse electric mode (TE) of the dielectric entity may correspond to the transverse electric mode (TE) of the external waveguide of the PCB. Thus, the arrangement of the microstrip line and the dielectric entity allow a transition from the transverse electromagnetic mode (TEM) of the microstrip line to the transverse electric mode (TE) of an external waveguide, such as the waveguide of the PCB. The microstrip line may represent a conductive layer with a low impedance. The external waveguide interface may have a high impedance. The waveguide of the PCB may be a rectangular waveguide.

The arrangement of the microstrip line and the dielectric entity in the eWLB package corresponds to inserting an end of the microstrip line into a perpendicular waveguide represented by the dielectric entity, whose one end is short-circuited, wherein the dielectric entity has a dimension perpendicular to the microstrip line equaling a quarter of a wavelength for which the microstrip line is designed. The dielectric entity may represent a back short waveguide. A back short waveguide is a waveguide, wherein one end of the waveguide is short-circuited. This allows an electric current on the end of the microstrip line to couple to a magnetic field of a transverse electric mode, such as the magnetic field of a TE₁₀ dominant mode, of the waveguide and, thus, of the external waveguide.

An impedance transformation may be achieved by controlling the length and width of the end of the microstrip line arranged below the dielectric entity; the dimension of the dielectric entity being perpendicular to the microstrip line equaling a quarter of a wavelength; and an opening size between the dielectric entity and the external waveguide.

The end part of the microstrip line may be referred to as “microstrip line probe” or “probe”. The microstrip line may be referred to as “redistribution layer (RLD)”. The microstrip line may be a metal pattern formed on a substrate. The microstrip line may be a coplanar waveguide (CPW) line. The microstrip line may be at least partly arranged (e.g. patterned) on a surface of the mold. The microstrip line may be arranged between the mold and the connection side of the eWLB package. The microstrip line may comprise one or more radio frequency (RF) lines and/or one or more direct current (DC) lines.

Since the dimension of the dielectric entity perpendicular to the microstrip line is a quarter of the wavelength, the dielectric entity is configured to provide a waveguide back short function. In other words, the dielectric entity represents a waveguide back short. This allows implementing by the dielectric entity a transformer, e.g. impedance transformer, from a transverse electromagnetic mode (TEM) of the microstrip line to a transverse electric mode (TE) of the waveguide of the PCB. For implementing a waveguide transition, i.e. a transition of signals, such as RF signals, travelling via the microstrip line to signals travelling through the waveguide in the PCB when the eWLB package is arranged on the PCB it is sufficient to have one microstrip line because the dielectric entity may provide by itself the waveguide back short function that allows for the waveguide transition operation. This allows a low loss transition and wider RF bandwidth performance, especially by selecting a suitable low loss dielectric entity made of a material with a suitable low dielectric constant (Dk).

The dielectric entity and the end part of the microstrip line may form a waveguide transition, such as an input and output waveguide transition, for an external waveguide port, i.e. for an external waveguide. The external waveguide may be fore example the waveguide of the PCB.

The connection elements may be configured to be welded to the PCB in order for the eWLB package to be connected via the connection elements to the PCB.

In an implementation form of the first aspect, multiple connection elements electrically connected to ground of the eWLB package of the connection elements are adapted and arranged at the connection side of the eWLB package such that they provide a galvanic connection between the ground of the eWLB package, ground of the dielectric entity and the waveguide of the PCB when the eWLB package is connected via the connection elements to the PCB and the dielectric entity and the end part of the microstrip line are aligned with the waveguide.

That is, the multiple connection elements may border the waveguide of the PCB when the eWLB package is connected via the connection elements to the PCB and the dielectric entity and the end part of the microstrip line are aligned with the waveguide. In other words, the multiple connection elements may be configured to constitute equivalent waveguide sidewalls. The term “electric connection” may be used as a synonym for the term galvanic connection. A galvanic connection between two parts refers to a creation of a direct electrical connection between the two parts, optionally using a conductive intermediate part, such as the aforementioned multiple connection elements (e.g. solder balls or solder leads).

The multiple connection elements of the connection elements of the eWLB package may be configured to provide the galvanic connection between the ground of the eWLB package, ground of the dielectric entity and the waveguide of the PCB using ball grid array (BGA) based connectivity.

The multiple connection elements may be configured to connect a waveguide transition (provided by the end of the microstrip line and the dielectric entity) of the eWLB package to an external waveguide port, e.g. the waveguide port of the waveguide of the PCB. The multiple connection elements of the eWLB package allow minimizing a signal leakage and signal losses that may occur at the transition from the eWLB package to the waveguide of the PCB. The galvanic connection that may be provided by the multiple connection elements of the eWLB package between the ground of the eWLB package, ground of the dielectric entity and the waveguide of the PCB increases a coupling efficiency between the microstrip line of the eWLB package and the waveguide of the PCB, especially the waveguide port of the waveguide of the PCB.

Optionally, in the case of frequencies above 100 GHz (e.g. the D frequency band, i.e. frequencies between 110 and 175 GHz, or frequencies between 130 and 175 GHz) of electromagnetic waves traveling via the microstrip line of the eWLB package, a pitch between the multiple connection elements may be less than 300 μm, optionally between 200 μm and 300 μm. This allows minimizing signal leakage. The term “distance” may be used as a synonym for the term “pitch”.

In an implementation form of the first aspect, the multiple connection elements are configured to be connected to an intermediate PCB carrier. The PCB carrier may be adapted and arranged such that it provides a galvanic connection between the ground of the eWLB package and the waveguide of the PCB when the eWLB package is connected via the PCB carrier to the PCB and the dielectric entity and the end part of the microstrip line are aligned with the waveguide. The connection elements may be configured to be welded to the PCB carrier. The PCB carrier may be configured to be welded to the PCB in order for the eWLB package to be connected via the PCB carrier to the PCB.

In an implementation form of the first aspect, one or more of the multiple connection elements are electrically connected with a ground metal enclosure of the dielectric entity and the ground metal enclosure comprises a passageway opening in a surface of the ground metal enclosure facing the microstrip line.

The metal enclosure of the dielectric entity may be connected to ground of the eWLB package. The metal enclosure represents ground of the dielectric entity. The passageway opening may be referred to as “opening slot”.

In an implementation form of the first aspect, the ground metal enclosure comprises one or more micro metal vias and/or one or more cavities with metal walls.

That is, the metal enclosure may be formed using one or more micro metal vias and/or one or more cavities with metal walls. The one or more micro metal vias and/or the one or more cavities with metal walls may realize sidewalls of the dielectric entity. The surface of the metal enclosure facing a side of the eWLB package that is opposite to the connection side of the eWLB package may be referred to as “top metal surface” and the surface of the metal enclosure facing the connection side of the eWLB package may be referred to as “bottom metal surface”. The top and bottom metal surfaces may be metal layers of the dielectric material (e.g. PCB substrate, glass substrate or liquid crystal polymer substrate) of the dielectric entity. The electrical connection of the one or more connection elements of the multiple connection elements with the ground metal enclosure may constitute equivalent waveguide sidewalls for guiding the signals from the microstrip line in the form of electromagnetic waves (e.g. RF signals in the form of radio waves) to the waveguide of the PCB.

The dielectric entity, e.g. the ground metal enclosure, may optionally comprise one or more fiducials for aligning the dielectric entity in the correct position in the eWLB package, e.g. with regard to the microstrip line.

In an implementation form of the first aspect, one or more of the multiple connection elements are electrically connected with ground of the microstrip line.

The microstrip line may comprise a ground layer. The one or more of the multiple connection elements may be electrically connected with the ground layer of the microstrip line.

In an implementation form of the first aspect, the dielectric entity has a rectangular cuboid shape. That is, the dielectric entity may represent a rectangular waveguide structure.

In an implementation form of the first aspect, the dielectric entity is made of at least one of: one or more PCB laminate materials, glass, and one or more liquid crystal polymer materials.

The dielectric entity may be made of at least one of one or more PCB laminate substrates, a glass substrate, and one or more liquid crystal polymer substrates. Using glass (e.g. glass substrate) and/or one or more liquid crystal polymer materials (e.g. one or more liquid crystal polymer substrates) provides a better production tolerance compared to using one or more PCB laminate materials (e.g. one or more PCB laminate substrates). Especially, using glass (e.g. glass substrate) and/or one or more liquid crystal polymer materials (e.g. one or more liquid crystal polymer substrates) provides better reliability and process yield. This may be especially true for high frequencies usable by the integrated circuit e.g. for communication via the microstrip line, such as frequencies greater than 100 GHz. The dielectric entity optionally being made of one or more PCB laminate materials means that the dielectric entity may be based on PCB technology. The above mentioned materials have a low dielectric constant (Dk) and, thus, allow implementing a low loss dielectric entity. PCB laminate materials have low costs. Glass has medium costs.

In an implementation form of the first aspect, the wavelength is a mid-wavelength of a frequency range comprising frequencies that are greater than 100 GHz.

The aforementioned wavelength is the wavelength used for describing the dimension of the dielectric entity being perpendicular to the microstrip line that equals a quarter of the wavelength. That is, the aforementioned wavelength is the wavelength for which the microstrip is designed. The size of the dielectric entity arranged in the mold may be directly proportional to the mentioned wavelength. Thus, the dielectric entity may be easily incorporated into the package. For example, the frequency range may be the D frequency band that comprises frequencies between 110 and 175 GHz. Optionally, the frequency range comprises frequencies between 130 and 175 GHz. The frequency range may be used by the integrated circuit of the eWLB package, e.g. for communication via the microstrip line. Thus, the frequency range may be referred to as “used frequency range”. The eWLB package may be used as a high frequency package for frequencies greater than 100 GHz (f>100 GHz). The eWLB package may be configured to be used in millimeter wave and/or sub-Terahertz applications.

In an implementation form of the first aspect, the eWLB package comprises a passivation layer being arranged between the dielectric entity and the microstrip line. In addition or alternatively, the eWLB package may comprise a passivation layer being arranged between the microstrip line and the connection elements.

In an implementation form of the first aspect, the connection elements are solder balls or solder leads.

That is, the connection elements may be solder bumps that may be implemented as balls shape (i.e. solder balls) or leads shape (i.e. solder leads). The solder leads may have a square or a rectangular form. The solder leads may be printed solder leads.

Optionally, in the case of frequencies above 100 GHz (e.g. the D frequency band, i.e. frequencies between 110 and 175 GHz, or frequencies between 130 and 175 GHz) of electromagnetic waves traveling via the microstrip line of the eWLB package, a diameter of the solder bumps may be between 100 μm and 150 μm.

In an implementation form of the first aspect, the solder leads have a cube shape or a rectangular cuboid shape.

The eWLB package according to the first aspect may be used for designing high frequencies chipset that are configured to operate in at least one of the following frequency bands: E frequency band (71 to 76 GHz and/or 81 to 86 GHz), W frequency band (92 to 115 GHz), D frequency band (110 to 175 GHz), and G frequency band (220 to 325 GHz).

For example, the eWLB package may be used for a single or multiple channel chip. The eWLB package may be used for a single waveguide or multiple waveguides. In the case of multiple waveguides, i.e. multiple waveguide ports, the eWLB package may comprise for each waveguide port a respective dielectric entity and a respective microstrip line, where an end part of the respective microstrip line is arranged below the respective dielectric entity.

For example, the eWLB package of the first aspect may be used in a phase array front end implementation (e.g. at high frequency), enabling beam steering function with an antenna, such as a flat antenna. The phase array front end implementation may be a phase array device, e.g. a phase array front end device.

In order to achieve the eWLB package according to the first aspect of the disclosure, some or all of the implementation forms and optional features of the first aspect, as described above, may be combined with each other.

A second aspect of this disclosure provides a system. The system comprises a eWLB package according to the first aspect of this disclosure, as described above. The system comprises a printed circuit board (PCB) with a waveguide in the form of a passageway opening in the PCB. The eWLB package is connected via the connection elements of the eWLB package to the PCB such that the dielectric entity and the end part of the microstrip line are aligned with the waveguide of the PCB.

The above description of the eWLB package according to the first aspect of this disclosure is correspondingly valid for the system according to the second aspect of this disclosure.

The system of the second aspect and its implementation forms and optional features achieve the same advantages as the eWLB package of the first aspect and its respective implementation forms and respective optional features.

A third aspect of this disclosure provides an embedded wafer level ball grid array package (eWLB package). The eWLB package comprises a mold enclosing an integrated circuit, and a microstrip line electrically connected with the integrated circuit. The eWLB package is configured to be connected via connection elements of a connection side of the eWLB package to a printed circuit board (PCB) with a waveguide in the form of a passageway opening in the PCB such that a part of the microstrip line is aligned with the waveguide. Multiple connection elements electrically connected to ground of the eWLB package of the connection elements are adapted and arranged at the connection side of the eWLB package such that they provide a galvanic connection between the ground of the eWLB package and the waveguide of the PCB when the eWLB package is connected via the connection elements to the PCB and the part of the microstrip line is aligned with the waveguide.

That is, the multiple connection elements border the waveguide of the PCB when the eWLB is connected via the connection elements to the PCB and the part of the microstrip line is aligned with the waveguide. In other words, the multiple connection elements may be configured to constitute equivalent waveguide sidewalls.

The multiple connection elements of the connection elements of the eWLB package may be configured to provide the galvanic connection between the ground of the eWLB package and the waveguide of the PCB using ball grid array (BGA) based connectivity.

The multiple connection elements of the eWLB package allow minimizing a signal leakage and signal losses that may occur at the transition from the eWLB package to the waveguide of the PCB. The galvanic connection that may be provided by the multiple connection elements of the eWLB package between the ground of the eWLB package and the waveguide of the PCB increases a coupling efficiency between the microstrip line of the eWLB package and the waveguide of the PCB, especially the waveguide port of the waveguide of the PCB.

Optionally, in the case of frequencies above 100 GHz (e.g. the D-Band, i.e. frequencies between 110 and 175 GHz) of electromagnetic waves traveling via the microstrip line of the eWLB package, a pitch between the multiple connection elements may be less than 300 μm, optionally between 200 μm and 300 μm. This allows minimizing signal leakage.

The eWLB package according to the third aspect may be used for designing high frequencies chipset that are configured to operated in at least one of the following frequency bands: E frequency band (71 to 76 GHz and/or 81 to 86 GHz), W frequency band (92 to 115 GHz), D frequency band (110 to 175 GHz), and G frequency band (220 to 325 GHz).

For example, the eWLB package may be used for a single or multiple channel chip. The eWLB package may be used for a single waveguide or multiple waveguides. In the case of multiple waveguides, i.e. multiple waveguide ports, the eWLB package may comprise for each waveguide port a respective microstrip line, where an end of the respective microstrip line is arranged below the respective dielectric entity.

For example, the eWLB package of the third aspect may be used in a phase array front end implementation (e.g. at high frequency), enabling beam steering function with an antenna, such as a flat antenna. The phase array front end implementation may be a phase array device, e.g. a phase array front end device.

The above description of the eWLB package according to the first aspect of this disclosure is correspondingly valid for the eWLB package according to the third aspect of this disclosure.

The eWLB package of the third aspect and its implementation forms and optional features achieve the same advantages as the eWLB package of the first aspect and its respective implementation forms and respective optional features.

In order to achieve the eWLB package according to the third aspect of the disclosure, some or all of the implementation forms and optional features of the third aspect, as described above, may be combined with each other.

A fourth aspect of this disclosure provides a system. The system comprises a eWLB package according to the third aspect of this disclosure, as described above. The system comprises a printed circuit board (PCB) with a waveguide in the form of a passageway opening in the PCB. The eWLB package is connected via the connection elements of the eWLB package to the PCB such that a part of the microstrip line of the eWLB package is aligned with the waveguide of the PCB. The multiple connection elements of the eWLB package provide a galvanic connection between the ground of the eWLB package and the waveguide of the PCB.

The above description of the eWLB package according to the first aspect and the eWLB package according to the third aspect of this disclosure is correspondingly valid for the system according to the fourth aspect of this disclosure.

The system of the fourth aspect and its implementation forms and optional features achieve the same advantages as the eWLB package of the first aspect and its respective implementation forms and respective optional features.

All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof.

### BRIEF DESCRIPTION OF DRAWINGS

The above described aspects and implementation forms will be explained in the following description of specific embodiments in relation to the enclosed drawings, in which

FIG. 1 shows an example of an embedded wafer level ball grid array package (eWLB package) according to an embodiment of this disclosure and an example of a system according to an embodiment of this disclosure.

FIG. 2 shows an example of an embedded wafer level ball grid array package (eWLB package) according to an embodiment of this disclosure and an example of a system according to an embodiment of this disclosure.

FIG. 3 shows an example of an arrangement of the dielectric entity and the microstrip line of the eWLB package of FIG. 1.

FIG. 4(a) shows a bottom view of an example of an implementation form of the dielectric entity of the eWLB package of FIG. 1.

FIG. 4(b) shows a bottom view of an example of an implementation form of the dielectric entity of the eWLB package of FIG. 1.

FIG. 5(a) shows a bottom view of an example of an implementation form of the eWLB package of FIG. 1.

FIG. 5(b) shows a bottom view of an example of an implementation form of the eWLB package of FIG. 1.

FIG. 6 shows an example of an implementation form of the eWLB package of FIG. 1.

FIG. 7 shows an example of an implementation form of the eWLB package of FIG. 1.

Same elements shown in the Figures (FIGs.) are labeled with the same reference sign, and may be implemented likewise. The proportions and dimensions of the elements shown in the FIGs. do not represent the eWLB package or system to scale, but are merely chosen to describe the structure and function of the eWLB package or system.

### DETAILED DESCRIPTION OF EMBODIMENTS

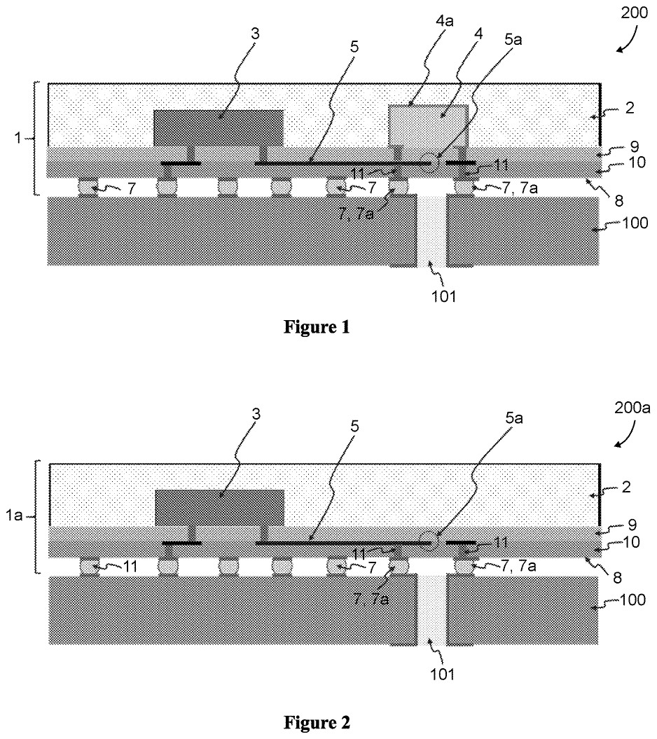

FIG. 1 shows an example of an embedded wafer level ball grid array package (eWLB package) according to an embodiment of this disclosure and an example of a system according to an embodiment of this disclosure. The eWLB package 1 of FIG. 1 is an example of the eWLB package according to the first aspect of the disclosure. Thus, the description of the eWLB package according to the first aspect of the disclosure is correspondingly valid for the eWLB package 1 of FIG. 1. The system 200 of FIG. 1 is an example of the system according to the second aspect of the disclosure. Thus, the description of the system according to the second aspect of the disclosure is correspondingly valid for the system 200 of FIG. 1.

The eWLB package 1 of FIG. 1 comprises a mold 2 enclosing an integrated circuit 3, a dielectric entity 4 arranged in the mold 2, and a microstrip line 5 electrically connected with the integrated circuit 3. In a direction towards a connection side 8 of the eWLB package 1, an end part 5a of the microstrip line 5 is arranged below the dielectric entity 4. The connection side 8 comprises connection elements 7. According to FIG. 1, the connection elements 7 are solder balls. This is only by way of example and, the connection elements 7 may be differently implemented. For example, the connection elements 7 may be solder leads.

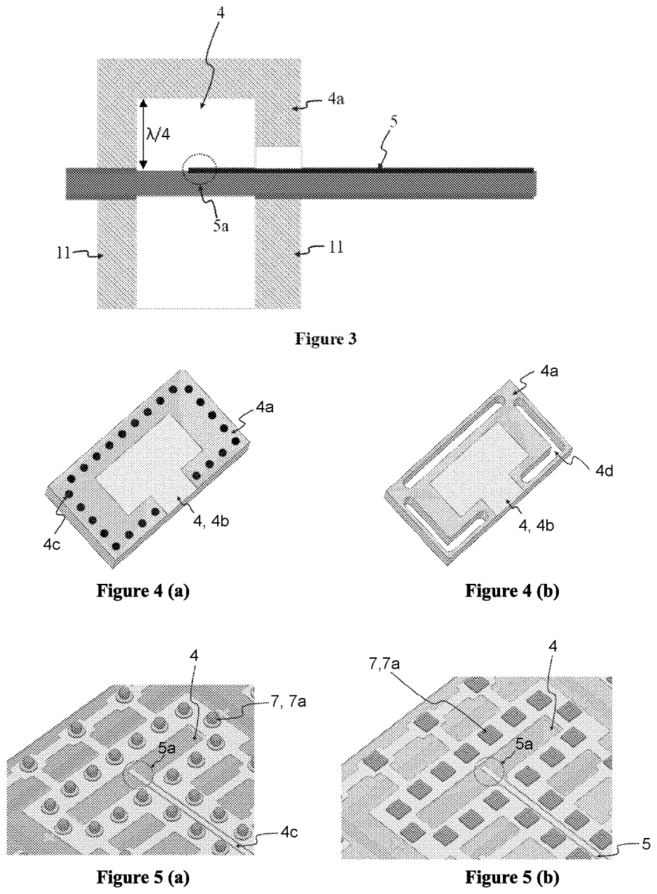

The dielectric entity 4 has a dimension perpendicular to the microstrip line 5 equaling a quarter of a wavelength (λ/4) for which the microstrip line 5 is designed. This is exemplarily shown in FIG. 3. As shown in FIG. 1, the eWLB package 1 is configured to be connected via the connection elements 7 to a printed circuit board 100 (PCB) with a waveguide 101 in the form of a passageway opening in the PCB 100, such that the dielectric entity 4 and the end part 5a of the microstrip line 5 are aligned with the waveguide 101. That is, as shown in FIG. 1 the PCB 100 comprises a waveguide 101 in the form of a passageway opening in the PCB 100. The eWLB package 1 may be arranged on the PCB 100 for an electrical connection to the PCB 100 using the connections elements 7 such that the dielectric entity 4 and the end part 5a of the microstrip line 5 are aligned with the waveguide 101. The PCB 100 may be referred to as “motherboard”.

As shown in FIG. 1, the eWLB package 1 may optionally comprise a passivation layer 9 being arranged between the dielectric entity 4 and the microstrip line 5. In addition or alternatively, the eWLB package 1 may optionally comprise a passivation layer 10 being arranged between the microstrip line 5 and the connection elements 7.

As shown in FIG. 1, multiple connection elements 7a electrically connected to ground of the eWLB package 1 of the connection elements 7 may be adapted and arranged at the connection side 8 of the eWLB package 1 such that they provide a galvanic connection between the ground of the eWLB package 1, ground of the dielectric entity 4 and the waveguide 101 of the PCB 100 when the eWLB package 1 is connected via the connection elements 7 to the PCB 100 and the dielectric entity 4 and the end part 5a of the microstrip line 5 are aligned with the waveguide 101. That is, as shown in FIG. 1, the multiple connection elements 7a may border the waveguide 101 of the PCB 100 when the eWLB package 1 is connected via the connection elements 7 to the PCB 100 and the dielectric entity 4 and the end part 5a of the microstrip line 5 are aligned with the waveguide 101. In other words, the multiple connection elements 7a may be configured to constitute equivalent waveguide sidewalls.

As shown in FIG. 1, the dielectric entity 4 may comprise a ground metal enclosure 4a that encloses the dielectric entity 4. The ground metal enclosure 4a comprises a passageway opening in a surface of the ground metal enclosure 4a facing the microstrip line 5. One or more of the multiple connection elements 7a of the connection elements 7 may be electrically connected with the ground metal enclosure 4a of the dielectric entity 4. As shown in FIG. 1, the electrical connection 11 of the one or more connection elements 7a of the multiple connection elements 7a with the ground metal enclosure 4a may constitute equivalent waveguide sidewalls for guiding the signals from the microstrip line 5 in the form of electromagnetic waves (e.g. RF signals in the form of radio waves) to the waveguide 101 of the PCB 100.

As shown in FIG. 1, the eWLB package 1 and the PCB 100 may form a system 200. The system 200 comprises the eWLB package 1 and the PCB 100. The eWLB package 1 of the system 200 is connected via the connection elements 7 of the eWLB package 1 to the PCB 100 of the system 200 such that the dielectric entity 4 and the end part 5a of the microstrip line 5 are aligned with the waveguide 101 of the PCB 100.

For further details on the eWLB package 1 and system 200 of FIG. 1 reference is made to the description of the eWLB package of the first aspect, the system of the second aspect and the description of FIGS. 3, 4(a), 4(b), 5(a), 5(b), 6 and 7.

FIG. 2 shows an example of an embedded wafer level ball grid array package (eWLB package) according to an embodiment of this disclosure and an example of a system according to an embodiment of this disclosure. The eWLB package 1a of FIG. 2 is an example of the eWLB package according to the third aspect of the disclosure. Thus, the description of the eWLB package according to the third aspect of the disclosure is correspondingly valid for the eWLB package 1a of FIG. 2. The system 200a of FIG. 2 is an example of the system according to the fourth aspect of the disclosure. Thus, the description of the system according to the fourth aspect of the disclosure is correspondingly valid for the system 200a of FIG. 2.

The eWLB package 1a of FIG. 2 comprises a mold 2 enclosing an integrated circuit 3, and a microstrip line 5 electrically connected with the integrated circuit 3. The eWLB package 1a is configured to be connected via connection elements 7 of a connection side 8 of the eWLB package 1a to a printed circuit board 100 (PCB) with a waveguide 101 in the form of a passageway opening in the PCB 100 such that a part 5a of the microstrip line 5 is aligned with the waveguide 101. That is, as shown in FIG. 2 the PCB 100 comprises a waveguide 101 in the form of a passageway opening in the PCB 100. The eWLB package 1 may be arranged on the PCB 100 for an electrical connection to the PCB 100 using the connections elements 7 such that the part 5a of the microstrip line 5 is aligned with the waveguide 101. According to FIG. 2, the connection elements 7 are solder balls. This is only by way of example and, the connection elements 7 may be differently implemented. For example, the connection elements 7 may be solder leads.

As shown in FIG. 2, multiple connection elements 7a electrically connected to ground of the eWLB package 1a of the connection elements 7 are adapted and arranged at the connection side 8 of the eWLB package 1a such that they provide a galvanic connection between the ground of the eWLB package 1a and the waveguide 101 of the PCB 100 when the eWLB package 1a is connected via the connection elements 7 to the PCB 100 and the part 5a of the microstrip line 5 is aligned with the waveguide 101.

That is, as shown in FIG. 2, the multiple connection elements 7a may border the waveguide 101 of the PCB 100 when the eWLB package 1a is connected via the connection elements 7 to the PCB 100 and the part 5a of the microstrip line 5 is aligned with the waveguide 101. In other words, the multiple connection elements 7a may be configured to constitute equivalent waveguide sidewalls. As shown in FIG. 2, the electrical connection 11 of the multiple connection elements 7a with ground of the eWLB package 1a may constitute equivalent waveguide sidewalls for guiding the signals from the microstrip line 5 in the form of electromagnetic waves (e.g. RF signals in the form of radio waves) to the waveguide 101 of the PCB 100.

As shown in FIG. 2, the eWLB package 1a may optionally comprise a passivation layer 9 being arranged between the mold 2 and the microstrip line 5. In addition or alternatively, the eWLB package 1 may optionally comprise a passivation layer 10 being arranged between the microstrip line 5 and the connection elements 7.

As shown in FIG. 2, the eWLB package 1a and the PCB 100 may form a system 200a. The system 200a comprises the eWLB package 1a and the PCB 100. The eWLB package 1a of the system 200a is connected via the connection elements 7 of the eWLB package 1a to the PCB 100 of the system 200a such that a part 5a of the microstrip line 5 of the eWLB package 1a is aligned with the waveguide 101 of the PCB 100. The multiple connection elements 7a of the eWLB package 1a provide a galvanic connection between the ground of the eWLB package 1a and the waveguide 101 of the PCB 100.

In the light of the above, the eWLB package 1a of FIG. 2 differs from the eWLB package 1 of FIG. 1, in that the eWLB package 1a of FIG. 2 does not necessarily comprise the dielectric entity 4 of the eWLB package 1 of FIG. 1. Thus, the description of the eWLB package 1 of FIG. 1 may be correspondingly valid for the eWLB package 1a of FIG. 2. For example, for providing RF signals in the form of radio waves from the integrated circuit 3 via the microstrip line 5 to the waveguide 101, the part 5a of the microstrip line 5 of the eWLB package 1a of FIG. 2 may optionally be a patch radiator for radiating radio waves in the direction of the waveguide 101. This is only by way of example and, thus, the eWLB package 1a may be differently implemented for providing signals (e.g. RF signals) from the microstrip line 5 to the waveguide 101 in the form of electromagnetic waves (e.g. radio waves).

For further details on the eWLB package 1a and system 200a of FIG. 2 reference is made to the description of the eWLB package of the third aspect, the system of the fourth aspect and the description of FIGS. 5(a), 5(b), 6 and 7.

FIG. 3 shows an example of an arrangement of the dielectric entity and the microstrip line of the eWLB package of FIG. 1. In the following mainly the arrangement of the dielectric entity and the microstrip line are described. For further details, reference is made to the description of the eWLB package 1 of FIG. 1.

As shown in FIG. 3, the end part 5a of the microstrip line 5 is arranged below the dielectric entity 4. The dielectric entity 4 has a dimension perpendicular to the microstrip line 5 equaling a quarter of a wavelength (λ/4) for which the microstrip line 5 is designed.

The wavelength λ may be a mid-wavelength of a frequency range comprising frequencies that are greater than 100 GHz. For example, the frequency range may be the D frequency band that comprises frequencies between 110 and 175 GHz. Optionally, the frequency range comprises frequencies between 130 and 175 GHz. The frequency range may be used by the integrated circuit 3 of the eWLB package 1, e.g. for communication via the microstrip line 5. The eWLB package may be used as a high frequency package for frequencies greater than 100 GHz (f>100 GHz). The eWLB package may be configured to be used in millimeter wave and/or sub-Terahertz applications.

Due to the dimension perpendicular to the microstrip line 5 of the dielectric entity 4 being a quarter of a wavelength (λ/4) for which the microstrip line 5 is designed, the dielectric entity 4 represents a short-circuited waveguide (with a dimension of a quarter of a wavelength (λ/4) for which the microstrip line 5 is designed). This allows at the end part 5a of the microstrip line 5, a transition of signals (e.g. RF signals) provided by the microstrip line 5 to electromagnetic waves travelling in the direction of the connection side 8 of the eWLB package 1 and, thus, in the direction of the waveguide 101 (when the eWLB package 1 is arranged on the PCB 100 such that the dielectric entity 4 and the end part 5a of the microstrip line 5 are aligned with the waveguide 101). For example, this allows a transformation of a transverse electromagnetic mode (TEM) of the microstrip line 5 to a transverse electric mode (TE) of the waveguide 101.

The arrangement of the microstrip line 5 and the dielectric entity 4 as well as the dimension perpendicular to the microstrip line 5 of the dielectric entity 4 being a quarter of a wavelength (λ/4) provide a back short function which allows a transition of signals from the end part 5a of the microstrip line 5 to electromagnetic waves traveling in the direction of the waveguide 101.

Optionally, as shown in FIG. 3, an electrical connection 11 of the one or more connection elements 7a of the multiple connection elements 7a of the eWLB package 1 with the ground metal enclosure 4a of the dielectric entity 4 may constitute equivalent waveguide sidewalls for guiding the signals from the microstrip line 5 in the form of electromagnetic waves (e.g. RF signals in the form of radio waves) to the waveguide 101 of the PCB 100.

FIG. 4(a) shows a bottom view of an example of an implementation form of the dielectric entity of the eWLB package of FIG. 1. The description of the eWLB package 1 of FIG. 1 is correspondingly valid for FIG. 4(a) and in the following mainly an optional feature of the dielectric entity of the eWLB package 1 of FIG. 4(a) is described.

In FIG. 4(a), the bottom metal layer of the ground metal enclosure 4a of the dielectric entity 4 is shown. As shown in FIG. 4(a), the ground metal enclosure 4a may comprises one or more micro metal vias 4c. The number of micro metal vias 4c shown in FIG. 4(a) is only by way of example and may be different. Further, FIG. 4(a) shows the passageway opening 4b in the surface of the ground metal enclosure 4a facing the microstrip line 5. The bottom metal layer of the ground metal enclosure 4a corresponds to this surface of the ground metal enclosure 4a. Thus, in the region of the passageway opening 4b of the ground metal enclosure the end part 5a of the microstrip line 5 may be arrange below the dielectric entity 4.

FIG. 4(b) shows a bottom view of an example of an implementation form of the dielectric entity of the eWLB package of FIG. 1. The description of the eWLB package 1 of FIG. 1 is correspondingly valid for FIG. 4(b) and in the following mainly an optional feature of the dielectric entity of the eWLB package 1 of FIG. 4(b) is described.

In FIG. 4(b), the bottom metal layer of the ground metal enclosure 4a of the dielectric entity 4 is shown. As shown in FIG. 4(b), the ground metal enclosure 4a may comprises one or more cavities 4d with metal walls. The number of cavities 4d with metal walls shown in FIG. 4(b) is only by way of example and may be different. Further, FIG. 4(b) shows the passageway opening 4b in the surface of the ground metal enclosure 4a facing the microstrip line 5. The bottom metal layer of the ground metal enclosure 4a corresponds to this surface of the ground metal enclosure 4a. Thus, in the region of the passageway opening 4b of the ground metal enclosure the end part 5a of the microstrip line 5 may be arrange below the dielectric entity 4.

FIG. 5(a) shows a bottom view of an example of an implementation form of the eWLB package of FIG. 1. The description of the eWLB package 1 of FIG. 1 is correspondingly valid for FIG. 5(a) and in the following mainly an optional feature of the eWLB package 1 of FIG. 5(a) is described.

As shown in FIG. 5(a), the connection elements 7 of the eWLB package 1 may be solder balls. That is, the connection elements 7 may be solder bumps that may be implemented as balls shape (i.e. solder balls). Optionally, in the case of frequencies above 100 GHz (e.g. the D frequency band, i.e. frequencies between 110 and 175 GHz, or frequencies between 130 and 175 GHz) of electromagnetic waves traveling via the microstrip line 5 of the eWLB package 1, a diameter of the solder bumps may be between 100 μm and 150 μm. In addition or alternatively, a pitch between the multiple connection elements 7a of the connection elements 7 may be less than 300 μm, optionally between 200 μm and 300 μm. This allows minimizing signal leakage. The number of the multiple connections elements 7a of the connection elements 7 shown in FIG. 5(a) is only by way of example and may be different.

As shown in FIG. 5(a), the multiple connection elements 7a may be arranged such that they border the dielectric entity 4, e.g. a part of the dielectric entity 4. This allows the multiple connection elements 7a to constitute equivalent waveguide sidewalls. As shown in FIG. 5(a), the end part 5a of the microstrip line is arranged below the dielectric entity 4. The description of FIG. 5(a) is correspondingly true for the eWLB package 1a of FIG. 2, where the dielectric entity 4 is not present.

FIG. 5(b) shows a bottom view of an example of an implementation form of the eWLB package of FIG. 1. The description of the eWLB package 1 of FIG. 1 is correspondingly valid for FIG. 5(b) and in the following mainly an optional feature of the eWLB package 1 of FIG. 5(b) is described.

As shown in FIG. 5(b), the connection elements 7 of the eWLB package 1 may be solder leads. That is, the connection elements 7 may be solder bumps that may be implemented as leads shape (i.e. solder leads). The solder leads may have a square or a rectangular form. That is, the solder leads may have a cube shape or a rectangular cuboid shape. The solder leads may be printed solder leads. Optionally, in the case of frequencies above 100 GHz (e.g. the D frequency band, i.e. frequencies between 110 and 175 GHz, or frequencies between 130 and 175 GHz) of electromagnetic waves traveling via the microstrip line 5 of the eWLB package 1, a pitch between the multiple connection elements 7a of the connection elements 7 may be less than 300 μm, optionally between 200 μm and 300 μm. This allows minimizing signal leakage. The number of the multiple connections elements 7a of the connection elements 7 shown in FIG. 5(b) is only by way of example and may be different.

As shown in FIG. 5(b), the multiple connection elements 7a may be arranged such that they border the dielectric entity 4, e.g. a part of the dielectric entity 4. This allows the multiple connection elements 7a to constitute equivalent waveguide sidewalls. As shown in FIG. 5(b), the end part 5a of the microstrip line is arranged below the dielectric entity 4. The description of FIG. 5(b) is correspondingly true for the eWLB package 1a of FIG. 2, where the dielectric entity 4 is not present.

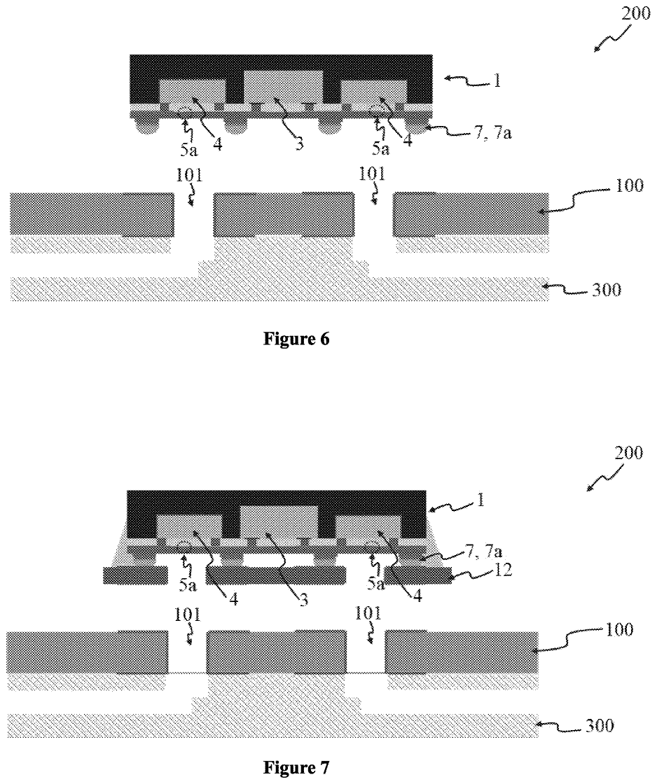

FIG. 6 shows an example of an implementation form of the eWLB package of FIG. 1. The description of the eWLB package 1 of FIG. 1 is correspondingly valid for FIG. 6 and in the following mainly optional features of the eWLB package 1 of FIG. 6 are described.

FIG. 6 shows a case in which the eWLB package is configured to provide and/or obtain electromagnetic waves to or from, respectively, two waveguide ports, i.e. two multiple waveguides 101 being present in the PCB 100. The number of waveguides is only by way of example and, thus, may be greater than two. The description of FIG. 6 is then correspondingly valid. As shown in FIG. 6, the eWLB package 1 may comprise for each waveguide 101 (i.e. each waveguide port) the dielectric entity 4 and the microstrip line 5 that is electrically connected to the integrated circuit 3. The end part 5a of each microstrip line 5 is arranged below the corresponding dielectric entity 4, and the dimension of the corresponding dielectric entity 4 perpendicular to the microstrip line 5 equals quarter of the wavelength for which the microstrip line 5 is designed. Due to the arrangement and dimension of each pair of the dielectric entity 4 and the microstrip line 5 signals may be provided from the integrated circuit 3 via the respective microstrip line 5 in the form of electromagnetic waves to the respective waveguide 101 of the PCB 100.

The description of FIGS. 1, 3, 4(a), 4(b), 5(a) and 5(c) is correspondingly valid for the eWLB package comprising multiple of the dielectric entity 4 for providing electromagnetic waves to multiple external waveguides 101.

As shown in FIG. 6, the PCB 100 may be arranged on a mechanical carrier 300. The mechanical carrier 300 may have multiple purposes, such as being a mechanical support, being a location of the waveguide distribution network (e.g. RF waveguide distribution network), being a heat sink and/or providing an antenna function. For example, the mechanical carrier 300 may be part of or may form an antenna, such as a flat antenna.

Thus, the distribution network for signals, such as RF signals, may not be implemented in layers of the PCB. This may be especially true for high frequencies, such as frequencies above 100 GHz. Such a distribution network may be designed by waveguides (e.g. rectangular waveguides), which may be small in size at high frequencies and with low losses. The eWLB package with the multiple input and output waveguide transitions formed by the multiple pairs of the dielectric entity 4 and the end part 5a of a corresponding microstrip line 5 is configured to interface the waveguides 101 of the PCB and, thus, the distribution network implemented at the mechanical carrier 300 below the PCB 100.

The eWLB package 1, the PCB 100 and the mechanical carrier 300 may form a system 200. That is, the system 200 may comprise the eWLB package 1, the PCB 100 and the mechanical carrier 300.

The description of FIG. 6 is correspondingly true for the eWLB package 1a of FIG. 2, where the dielectric entity 4 is not present.

FIG. 7 shows an example of an implementation form of the eWLB package of FIG. 1. The description of the eWLB package 1 of FIG. 1 is correspondingly valid for FIG. 7 and in the following mainly optional features of the eWLB package 1 of FIG. 7 are described.

The eWLB package 1 of FIG. 7 corresponds to the eWLB package 1 of FIG. 6 with an additional feature. Thus, reference is made to the description of the eWLB 1 of FIG. 6 for describing the eWLB 1 of FIG. 7 and in the following mainly the additional feature is described.

As shown in FIG. 7, the multiple connection elements 7a are configured to be connected to an intermediate PCB carrier 12. In the example, of FIG. 7 the multiple connection elements 7a are connected to the intermediate PCB carrier 12. This is only by way of example. The PCB carrier 12 may be adapted and arranged such that it provides a galvanic connection between the ground of the eWLB package 1 and the waveguides 101 of the PCB 100 when the eWLB package 1 is connected via the PCB carrier 12 to the PCB 100 and each dielectric entity 4 and the end part 5a of the corresponding microstrip line 5 are aligned with the corresponding waveguide 101. The description of FIG. 7 is correspondingly valid when the PCB 100 comprises only one waveguide 101 or more than two waveguides 101.

The connection elements 7 may be configured to be welded to the PCB carrier 12. The PCB carrier 12 may be configured to be welded to the PCB 100 in order for the eWLB package 1 to be connected via the PCB carrier 12 to the PCB 100. The intermediate PCB carrier 12 may be the effective component interface to the PCB 100.

The description of FIG. 7 is correspondingly true for the eWLB package 1a of FIG. 2, where the dielectric entity 4 is not present.

The eWLB packages of this disclosure, such as any one of FIGS. 1 to 7, may be used for a single or multiple channel chip. The eWLB packages may be used for a single external waveguide or multiple external waveguides. In the case of multiple waveguides, i.e. multiple waveguide ports, the eWLB packages may comprise for each waveguide port a respective dielectric entity and a respective microstrip line, where an end of the respective microstrip line is arranged below the respective dielectric entity (in case dielectric entities are present).

For example, the eWLB packages of this disclosure may be used in a phase array front end implementation (e.g. at high frequency), enabling beam steering function with an antenna, such as a flat antenna. The phase array front end implementation may be a phase array device, e.g. a phase array front end device.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

1. An embedded wafer level ball grid array package (1), eWLB package, comprising
a mold (2) enclosing an integrated circuit (3),
a dielectric entity (4) arranged in the mold (2), and
a microstrip line (5) electrically connected with the integrated circuit (3); wherein
in a direction towards a connection side (8) of the eWLB package (1) comprising connection elements (7), an end part (5a) of the microstrip line (5) is arranged below the dielectric entity (4);
the dielectric entity (4) has a dimension perpendicular to the microstrip line (5) equaling a quarter of a wavelength for which the microstrip line (5) is designed; and
the eWLB package (1) is configured to be connected via the connection elements (7) to a printed circuit board (100), PCB, with a waveguide (101) in the form of a passageway opening in the PCB (100), such that the dielectric entity (4) and the end part (5a) of the microstrip line (5) are aligned with the waveguide (101).

2. The eWLB package (1) according to claim 1, wherein
multiple connection elements (7, 7a) electrically connected to ground of the eWLB package (1) of the connection elements (7) are adapted and arranged at the connection side (8) of the eWLB package (1) such that they provide a galvanic connection between the ground of the eWLB package (1), ground of the dielectric entity (4) and the waveguide (101) of the PCB (100) when the eWLB package (1) is connected via the connection elements (7) to the PCB (100) and the dielectric entity (4) and the end part (5a) of the microstrip line (5) are aligned with the waveguide (101).

3. The eWLB package (1) according to claim 2, wherein
the multiple connection elements (7, 7a) are configured to be connected to an intermediate PCB carrier (12), and
the PCB carrier (12) is adapted and arranged such that it provides a galvanic connection between the ground of the eWLB package (1) and the waveguide (101) of the PCB (100) when the eWLB package (1) is connected via the PCB carrier (12) to the PCB (100) and the dielectric entity (4) and the end part (5a) of the microstrip line (5) are aligned with the waveguide (101).

4. The eWLB package (1) according to claim 2, wherein
one or more of the multiple connection elements (7, 7a) are electrically connected with a ground metal enclosure (4a) of the dielectric entity (4) and the ground metal enclosure (4a) comprises a passageway opening (4b) in a surface of the ground metal enclosure (4a) facing the microstrip line (5).

5. The eWLB package (1) according to claim 4, wherein
the ground metal enclosure (4a) comprises one or more micro metal vias (4c) and/or one or more cavities (4d) with metal walls.

6. The eWLB package (1) according to claim 2, wherein
one or more of the multiple connection elements (7, 7a) are electrically connected with ground of the microstrip line (5).

7. The eWLB package (1) according to claim 1, wherein
the dielectric entity (4) has a rectangular cuboid shape.

8. The eWLB package (1) according to claim 1, wherein
the dielectric entity (4) is made of at least one of: one or more PCB laminate materials, glass, and one or more liquid crystal polymer materials.

9. The eWLB package (1) according to claim 1, wherein
the wavelength is a mid-wavelength of a frequency range comprising frequencies that are greater than 100 GHz.

10. The eWLB package (1) according to claim 1, wherein
the eWLB package (1) comprises a passivation layer (9) being arranged between the dielectric entity (4) and the microstrip line (5), and/or
the eWLB package (1) comprises a passivation layer (10) being arranged between the microstrip line (5) and the connection elements (7).

11. The eWLB package (1) according to claim 1, wherein
the connection elements (7) are solder balls or solder leads.

12. The eWLB package (1) according to claim 11, wherein
the solder leads have a cube shape or a rectangular cuboid shape.

13. A system (200) comprising
an eWLB package (1) comprising a mold (2) enclosing an integrated circuit (3), and a microstrip line (5) electrically connected with the integrated circuit (3); wherein the eWLB package (1a) is configured to be connected via connection elements (7) of a connection side (8) of the eWLB package (1a) to a printed circuit board (100), PCB, with a waveguide (101) in the form of a passageway opening in the PCB (100) such that a part (5a) of the microstrip line (5) is aligned with the waveguide (101), and multiple connection elements (7, 7a) electrically connected to ground of the eWLB package (1a) of the connection elements (7) are adapted and arranged at the connection side (8) of the eWLB package (1a) such that they provide a galvanic connection between the ground of the eWLB package (1a) and the waveguide (101) of the PCB (100) when the eWLB package (1a) is connected via the connection elements (7) to the PCB (100) and the part (5a) of the microstrip line (5) is aligned with the waveguide (101), and
a printed circuit board (100), PCB, with a waveguide (101) in the form of a passageway opening in the PCB (100), wherein
the eWLB package (1) is connected via the connection elements (7) of the eWLB package (1) to the PCB (100) such that the dielectric entity (4) and the end part (5a) of the microstrip line (5) are aligned with the waveguide (101) of the PCB (100).

14. An embedded wafer level ball grid array package (1a), eWLB package, comprising
a mold (2) enclosing an integrated circuit (3), and
a microstrip line (5) electrically connected with the integrated circuit (3); wherein
the eWLB package (1a) is configured to be connected via connection elements (7) of a connection side (8) of the eWLB package (1a) to a printed circuit board (100), PCB, with a waveguide (101) in the form of a passageway opening in the PCB (100) such that a part (5a) of the microstrip line (5) is aligned with the waveguide (101), and
multiple connection elements (7, 7a) electrically connected to ground of the eWLB package (1a) of the connection elements (7) are adapted and arranged at the connection side (8) of the eWLB package (1a) such that they provide a galvanic connection between the ground of the eWLB package (1a) and the waveguide (101) of the PCB (100) when the eWLB package (1a) is connected via the connection elements (7) to the PCB (100) and the part (5a) of the microstrip line (5) is aligned with the waveguide (101).
